(19) United States
(12) Patent Application Publication
(10) Pub. No.: US 2023/0387161 A1
(43) Pub. Date: Nov. 30, 2023

(54) PHOTOELECTRIC SENSOR AND METHOD FOR FORMING SAME, AND ELECTRONIC DEVICE

(71) Applicants: SEMICONDUCTOR MANUFACTURING INTERNATIONAL (BEIJING) CORPORATION, Beijing (CN); SEMICONDUCTOR MANUFACTURING INTERNATIONAL (SHANGHAI) CORPORATION, Shanghai (CN)

(72) Inventors: Hongmin LIU, Beijing (CN); Qiangwei CUI, Beijing (CN); Changcheng GAO, Beijing (CN)

(73) Assignees: SEMICONDUCTOR MANUFACTURING INTERNATIONAL (BEIJING) CORPORATION, Beijing (CN); SEMICONDUCTOR MANUFACTURING INTERNATIONAL (SHANGHAI) CORPORATION, Shanghai (CN)

(21) Appl. No.: 17/963,292

(22) Filed: Oct. 11, 2022

(30) Foreign Application Priority Data
May 24, 2022 (CN) 202210571170.X

(51) Int. Cl. H01L 27/146

(52) U.S. Cl. CPC H01L 27/14625; H01L 27/1463; H01L 27/14685

(57) ABSTRACT

A photoelectric sensor and a method for forming same and an electronic device are provided. The photoelectric sensor includes: a base, having a light receiving surface and including a pixel unit region; and a plurality of light trapping grooves, arranged in a part of the base in a thickness direction in the pixel unit region and arranged on a side of the light receiving surface of the base, where a surface shape of each of the light trapping grooves is arcuate. The present disclosure helps improve photosensitive performance of the photoelectric sensor.

### RELATED APPLICATIONS

The present application claims priority to Chinese Patent Appln. No. 202210571170.X, filed May 24, 2022, the entire disclosure of which is hereby incorporated by reference.

### TECHNICAL FIELD

Embodiments and implementations of the present disclosure relate to the field of semiconductor manufacturing, and in particular, to a photoelectric sensor and a method for forming same, and an electronic device.

### BACKGROUND

A photoelectric sensor is a device for converting optical signals to electrical signals. An operating principle of the photoelectric sensor is based on a photoelectric effect. The photoelectric effect means that a corresponding electrical effect occurs when electrons of substances absorb energy of photons as light irradiates the substances.

For example, charge coupled device (CCD) image sensors and a CMOS image sensor convert optical images to electrical signals using a photoelectric conversion function and then output digital images. These sensors are widely used in digital cameras and other electronic optical devices. A time of flight (ToF) distance sensor projects a modulated infrared light source onto an object, a person, or a scene, and then ToF sensor captures reflected light. The sensor measures an intensity of light received by each pixel and a phase difference to obtain a highly reliable depth image and a grayscale image of the entire scene. The technology is applicable to various ranging scenarios such as autonomous driving, sweeping robots, and virtual reality (VR)/augmented reality (AR) modeling.

Photoelectric sensors generally have a set area of pixels for receiving optical signals. A higher optical transmittance of the pixel region brings larger optical sensitivity of a device.

However, photosensitive performance of the currently formed photoelectric sensors is to be improved.

### SUMMARY

A problem to be addressed in embodiments and implementations of the present disclosure is to provide a photoelectric sensor and a method for forming same and an electronic device, so as to improve photosensitive performance of the photoelectric sensor.

To address the above problem, one form of the present disclosure provides a photoelectric sensor, including: a base, having a light receiving surface and including a pixel unit region; and a plurality of light trapping grooves, arranged in a part of the base in a thickness direction in the pixel unit region and arranged on a side of the light receiving surface of the base, where a surface shape of each of the light trapping grooves is arcuate.

Another form of the present disclosure further provides a method for forming a photoelectric sensor, including: providing a base, where the base has a light receiving surface, the base includes a pixel unit region, and a mask layer covering the light receiving surface is formed on the base; patterning the mask layer to form a plurality of mask openings in the mask layer in the pixel unit region; and etching the base along the mask openings using an isotropic wet etching process to form a plurality of light trapping grooves, where a surface shape of each of the light trapping grooves is arcuate.

Yet another form of the present disclosure provides an electronic device, including the photoelectric sensor provided in the embodiments of the present disclosure.

Compared with existing technologies, the technical solutions of the embodiments of the present disclosure have the following advantages.

In photoelectric sensors provided in embodiments and implementations of the present disclosure, the surface shape of the light trapping groove is an arcuate surface, which helps increase a photosensitive area of the photoelectric sensor in the pixel unit region. Therefore, an optical path difference of incident light increases, which helps improve an optical localization capability of the photoelectric sensor. Moreover, a process of forming the light trapping groove with the arcuate surface is easy to operate, and parameters of the process are highly controllable, which help form light trapping grooves with relatively high morphological quality, thereby improving the photosensitive performance of the photoelectric sensor.

In methods for forming a photoelectric sensor provided in embodiments and implementations of the present disclosure, the base is etched along the mask openings using the isotropic wet etching process to form a plurality of light trapping grooves, and the surface shape of each of the light trapping grooves is an arcuate surface, which helps increase a photosensitive area of the photoelectric sensor in the pixel unit region. Therefore, an optical path difference of incident light increases, which helps improve an optical localization capability of the photoelectric sensor. Moreover, the etching using the isotropic wet etching process is less restricted by a lattice of a material of the base, parameters of the process are highly controllable, and sizes of and a spacing between the formed light trapping grooves can be controlled through the mask openings and the etching process, which improves process flexibility of forming the light trapping grooves, and therefore help form light trapping grooves with relatively high morphological quality, thereby improving the photosensitive performance of the photoelectric sensor.

### BRIEF DESCRIPTION OF THE DRAWINGS

FIG. 1 to FIG. 4 are schematic structural diagrams corresponding to steps in a method for forming a photoelectric sensor.

FIG. 5 to FIG. 7 are schematic structural diagrams of one form of a photoelectric sensor according to the present disclosure.

FIG. 8 to FIG. 13 are schematic structural diagrams corresponding to steps in one form of a method for forming a photoelectric sensor according to the present disclosure.

FIG. 14 to FIG. 16 are schematic structural diagrams corresponding to steps in another form of a method for forming a photoelectric sensor according to the present disclosure.

### DETAILED DESCRIPTION

It will be appreciated from the background that currently formed photoelectric sensors have a relatively poor photosensitive performance. Reasons for the relatively poor photosensitive performance of the currently formed photoelectric sensors are analyzed below in combination with a method for forming a photoelectric sensor.

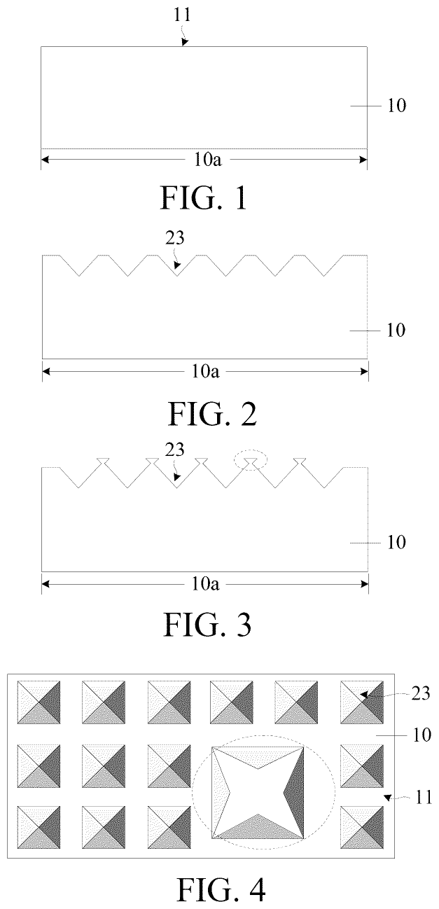

FIG. 1 to FIG. 4 are schematic structural diagrams corresponding to steps in a method for forming a photoelectric sensor.

Referring to FIG. 1, a base 10 is provided. The base 10 has a light receiving surface 11. The base 10 includes a pixel region (not shown). The pixel region includes a plurality of pixel unit regions 10a distributed in a matrix.

With reference to FIG. 2 to FIG. 4, in the pixel unit region 10a. The light receiving surface 11 of the base 10 is etched by using a wet etching process with an anisotropic etching rate for a different crystal direction, to form a light trapping groove 23. The light trapping groove 23 is an inverted pyramid structure.

Referring to FIG. 2, due to the different etching rates for different crystal directions, the light trapping groove 23 with the inverted pyramid structure can be formed. Therefore, the light trapping groove 23 with the inverted pyramid structure is restricted by a crystal direction of the base 10 thereof. In addition, it is difficult to control the anisotropic etching process of different crystal directions. Correspondingly, sizes of and a spacing between the light trapping grooves 23 with the inverted pyramid structure are restricted by a crystal direction thereof and the process, resulting in difficulty in forming a light trapping groove 23 with a controllable shape. Specifically, referring to FIG. 3, during the formation of the light trapping groove 23 with the inverted pyramid structure, the base 10 is prone to an undercut (shown by a dashed-line circle in FIG. 3), which leads to an unsuccessful inverted pyramid shape, thus affecting photosensitive performance of the photoelectric sensor. Referring to FIG. 4, FIG. 4 is a top view of a photoelectric sensor. The anisotropic etching process for a different crystal direction is easily affected by defects such as scratches on a surface of the base 10, which leads to an unnecessary inverted pyramid shape (shown by a dashed-line circle in FIG. 4), affecting photosensitive performance of the photoelectric sensor.

To address the described technical problem, embodiments and implementations of the present disclosure provide a method for forming a photoelectric sensor. Forms of the method includes: providing a base, where the base has a light receiving surface, the base includes a pixel unit region, and a mask layer covering the light receiving surface is formed on the base; patterning the mask layer to form a plurality of mask openings in the mask layer in the pixel unit region; and etching the base along the mask openings using an isotropic wet etching process to form a plurality of light trapping grooves, where a surface shape of each of the light trapping grooves is arcuate.

In the method for forming a photoelectric sensor provided in embodiments and implementations of the present disclosure, the base is etched along the mask openings using the isotropic wet etching process to form a plurality of light trapping grooves, and the surface shape of each of the light trapping grooves is an arcuate surface, which helps increase a photosensitive area of the photoelectric sensor in the pixel unit region. Therefore, an optical path difference of incident light increases, which helps improve an optical localization capability of the photoelectric sensor. Moreover, the etching using the isotropic wet etching process is less restricted by a lattice of a material of the base, parameters of the process are highly controllable, and sizes of and a spacing between the formed light trapping grooves can be controlled through the mask openings and the etching process, which improves process flexibility of forming the light trapping grooves, and therefore help form light trapping grooves with relatively high morphological quality, thereby improving the photosensitive performance of the photoelectric sensor.

In order to make the foregoing objectives, features, and advantages of embodiments and implementations of the present disclosure more apparent and easier to understand, specific embodiments and implementations of the present disclosure are described in detail below with reference to the accompanying drawings.

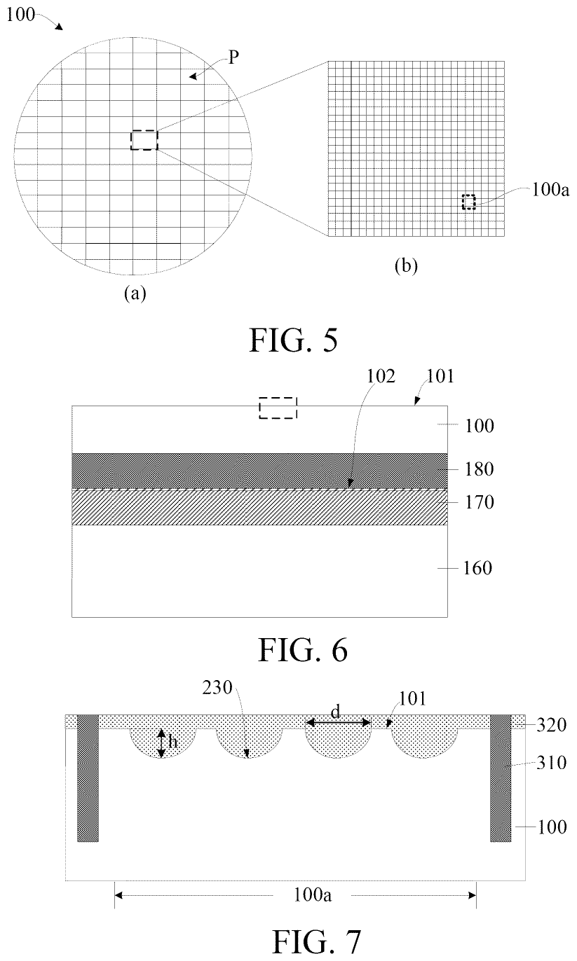

FIG. 5 to FIG. 7 are schematic structural diagrams of one form of a photoelectric sensor according to the present disclosure. FIG. 5(a) is a top view, FIG. 5(b) is a partial enlarged view of any photosensitive pixel region in FIG. 5(a), FIG. 6 is a cross-sectional view corresponding to FIG. 5(a), and FIG. 7 is a partial enlarged view of a position shown by dashed lines in FIG. 6.

The photoelectric sensor includes: a base 100, where the base 100 has a light receiving surface 101, and the base 100 includes a pixel unit region 100a; and a plurality of light trapping grooves 230, arranged in a part of the base 100 in a thickness direction in the pixel unit region 100a and arranged on a side of the light receiving surface 101 of the base 100, where a surface shape of each of the light trapping grooves 230 is an arcuate surface.

In some implementations, the photoelectric sensor is a time of flight (TOF) sensor, for example. Specifically, the photoelectric sensor may be a direct time of flight (DTOF) sensor.

In other implementations, the photoelectric sensor may be a charge coupled device (CCD) image sensor, a CMOS image sensor, an indirect time of flight (iTOF) sensor, or the like.

In some implementations, the base 100 is a silicon base. That is to say, a material of the base 100 is silicon.

In some implementations, the base 100 includes a photosensitive pixel region P, and the photosensitive pixel region P includes a plurality of pixel unit regions 100a distributed in a matrix.

The photosensitive pixel region P is used for receiving optical signals so as to convert the optical signals to electrical signals.

In the base 100, a plurality of photosensitive pixel regions P is arranged. The plurality of photosensitive pixel regions P is distributed in a matrix. The pixel unit region 100a is used for forming pixels.

In some implementations, the base 100 has a light receiving surface 101. The light receiving surface 101 is a surface for receiving light.

Specifically, the base 100 is a pixel wafer, and the light receiving surface 101 is a first surface. The base 100 further includes a second surface 102 opposite to the first surface.

In some implementations, the base 100 is a backside illumination (BSI) pixel wafer. Correspondingly, the light receiving surface 101 is a back side of the wafer, and the second surface 102 is a front side of the wafer.

In some implementations, only a part of the photosensitive pixel region P and the pixel unit region 100a is shown in the figure. The pixel unit region 100a may further include device structures such as a photoelectric element (for example, a photodiode). The photodiode may be a BSI single-photon avalanche diode (SPAD). For simplicity, detailed structures of the above components are not shown in this embodiment.

In some implementations, the base 100 is defined as a first base 100. In this case, the photoelectric sensor further includes a second base 160 bonded to the second surface 102 of the first base 100. Specifically, the second base 160 is a logic wafer.

The second base 160 is a logic wafer configured to analyze and process electrical signals provided by the pixel wafer.

Arranging the photosensitive pixel region P and a logic region on the two wafers respectively and bonding the pixel wafer to the logic wafer can obtain a larger pixel area, and help shorten a path through which light passes to reach the photoelectric element, and reduce scattering of the light, so that the light is more focused, thereby improving a photosensitive capability of the photoelectric sensor in a weak light environment, and reducing system noise and crosstalk.

In some implementations, the second base 160 may be a silicon base. In other implementations, the second base may be made of other materials such as germanium, silicon germanium, silicon carbide, gallium arsenide, or indium gallium. The second base may alternatively be other types of bases such as a silicon base on an insulator or a germanium base on an insulator.

In some implementations, the second base 160 further includes a logic transistor (not shown). The logic transistor is configured to perform logic processing on the electrical signals provided by the pixel wafer. Specifically, the logic transistor may include a logic gate structure located on the second base 160 and a logic drain region and a logic source region respectively located in the second bases 160 on two sides of the logic gate structure.

In some implementations, the second surface 102 of the first base 100 is bonded to the second base 160 by hybrid bonding.

Specifically, in some implementations, a first interconnecting structure 180 is formed on the second surface 102 of the first base 100, and a second interconnecting structure 170 is formed on the second base 160. The pixel wafer may be bonded to the logic wafer by dielectric bonding and metal bonding between the first interconnecting structure 180 and the second interconnecting structure 170.

The first interconnecting structure 180 may be a first metal line. Alternatively, the first interconnecting structure 180 is a first through-silicon via (TSV) interconnecting structure. Alternatively, the first interconnecting structure 180 includes a first TSV interconnecting structure and a first metal line on the first TSV interconnecting structure. The second interconnecting structure 170 may be a second metal line. Alternatively, the second interconnecting structure 170 is a second TSV interconnecting structure. Alternatively, the second interconnecting structure 170 includes a second TSV interconnecting structure and a second metal line on the second TSV interconnecting structure.

It should be noted that, the above manner of bonding the first base 100 to the second base 160 is merely an example, and bonding between the first base 100 and the second base 160 is not limited thereto. For example, in other implementations, the first base may be directly bonded to the second base (for example, by fusion bonding and anodic bonding). Alternatively, the first base may be indirectly bonded to the second base (for example, by metal eutectic bonding, thermocompression bonding, and adhesive bonding).

In some implementations, the light receiving surface 101 of the first base 100 is a thinned light receiving surface 101.

The light trapping groove 230 helps improve an optical transmittance of the photosensitive pixel region P and increase photoelectric conversion efficiency, thereby improving optical sensitivity of the photoelectric sensor.

Specifically, the light trapping groove 230 is arranged above the photoelectric element, which can slow down a change of a refractive index between the air and the first surface 101, and reduce a high reflectivity at an interface caused by a sudden change of the refractive index, so that more light can enter the photoelectric element, and a transmittance of the incident light can be improved. In addition, arranging the light trapping groove 230 in the pixel unit region 100a of the first surface 101 can help disperse the incident light to a plurality of angles, and increase an effective path of the light, thereby realizing trapping of the light.

In some implementations, the surface shape of the light trapping groove 230 is arcuate, which helps increase a photosensitive area of the photoelectric sensor in the pixel unit region 100a. Therefore, an optical path difference of incident light increases, which helps improve an optical localization capability of the photoelectric sensor. Moreover, a process of forming the light trapping groove 230 with the arcuate surface is easy to operate, and parameters of the process are highly controllable, which help form light trapping grooves 230 with relatively high morphological quality, thereby improving the photosensitive performance of the photoelectric sensor.

A plurality of light trapping grooves 230 is arranged. The plurality of light trapping grooves 230 is distributed in a matrix, so as to improve a density of light trapping grooves 230 in each pixel unit region 100a, thereby helping further increase the optical transmittance.

The density of the light trapping grooves 230 is a ratio of an area of openings of all light trapping grooves 230 in the photosensitive pixel region P to an area of the photosensitive surface 101 of the photosensitive pixel region P.

In some implementations, the surface shape of the light trapping groove 230 is hemispherical, so that the morphological quality of the light trapping groove 230 is relatively high, which helps further increase the photosensitive area of the photoelectric sensor and improve the optical localization capability of the photoelectric sensor, thereby further improving the photosensitive performance of the photoelectric sensor.

It should be noted that a maximum depth h of the light trapping groove 230 should be neither excessively large nor excessively small. If the maximum depth h of the light trapping groove 230 is excessively large, a thickness of the remaining base 100 at a bottom of the light trapping groove 230 is excessively small. That is to say, for light incident on the bottom of the light trapping groove 230, photons cannot be absorbed effectively. In particular, for incident light with a relatively longer wavelength such as a near-infrared ray, the base 100 at the bottom of the light trapping groove 230 absorbs the light much less effectively, affecting the absorption of the light by the photoelectric sensor. If the maximum depth h of the light trapping groove 230 is excessively small, it is difficult to form a relatively desirable arcuate surface shape for the light trapping groove 230, or even the surface shape approximates a flat surface shape, resulting in excessively few reflections of the incident light and difficulty in increasing the optical path difference. As a result, it is difficult to improve the photosensitive performance of the photoelectric sensor. Therefore, in some implementations, the maximum depth h of the light trapping groove 230 ranges from 150 nm to 600 nm.

The maximum depth h of the light trapping groove 230 is a depth at the lowest point of the light trapping groove 230 with the arcuate surface.

It should be further noted that a transverse opening size d of the light trapping groove 230 should be neither excessively large nor excessively small. If the transverse opening size d of the light trapping groove 230 is excessively large, a spacing between adjacent light trapping grooves 230 is excessively small, that is, an area of a platform of the light receiving surface 101 between adjacent light trapping grooves 230 is excessively small. During the etching process for forming the light trapping groove 230, regions that do not need to be etched are required to be protected using an etching mask, that is, an etching mask (not shown) is further formed on the platform of the light receiving surface 101 between adjacent light trapping grooves 230. Therefore, the area of the platform of the light receiving surface 101 between adjacent light trapping grooves 230 is excessively small, which tends to cause the etching mask on the platform of the light receiving surface 101 between adjacent light trapping grooves 230 to fall into a pickling tank during the etching process for forming the light trapping groove 230. As a result, the pickling tank is polluted, affecting other subsequent manufacture procedures using the pickling tank. If the transverse opening size d of the light trapping groove 230 is excessively small, the spacing between adjacent light trapping grooves 230 is excessively large. That is to say, if the area of the platform of the light receiving surface 101 between adjacent light trapping grooves 230 is excessively large, an area percentage of the area of the platform of the light receiving surface 101 between adjacent light trapping grooves 230 in the pixel unit region 100a is excessively large. Correspondingly, if the density of light trapping grooves 230 is excessively small, it is difficult to obtain a relatively large photosensitive area, resulting in difficulty in improving the performance of the photoelectric sensor. Therefore, in some implementations, the transverse opening size d of the light trapping groove 230 ranges from 150 nm to 600 nm.

In some implementations, the photoelectric sensor further includes a light-transmissive layer 320 filling the light trapping groove 230 and covering the light receiving surface 101 of the pixel unit region 100a.

Filling the light trapping groove 230 with the light-transmissive layer 320 helps ensure an effect of the light trapping groove 230 for improving the optical transmittance of the photosensitive pixel region P, thereby improving process integration and process compatibility. In addition, the light-transmissive layer 320 is further configured to planarize each film layer on the light receiving surface 101.

In some implementations, a material of the light-transmissive layer 320 includes silicon oxide, silicon nitride, silicon oxynitride, or silicon carbide.

In some implementations, the photoelectric sensor further includes a light isolation structure 310 arranged in the base 100 between adjacent pixel unit regions 100a.

The light isolation structure 310 is configured to reduce optical crosstalk between adjacent pixel unit regions 100a.

In some implementations, a material of the light isolation structure 310 includes one or more of tungsten, aluminum, copper, titanium, titanium nitride, tantalum, tantalum nitride, silicon oxide, aluminum oxide, or polysilicon.

Specifically, In some implementations, the photoelectric sensor further includes a conformal dielectric layer (not shown) arranged between the light-transmissive layer 320 and the base 100 and between the light isolation structure 310 and the base 100.

The conformal dielectric layer can electrically isolate adjacent pixel unit regions 100a, which helps prevent electrical crosstalk between the adjacent pixel unit regions 100a. A conformal dielectric layer 140 located on a surface between the light isolation structure 310 and the base 100 can electrically isolate the adjacent pixel unit regions 100a, which correspondingly helps prevent electrical crosstalk between the adjacent pixel unit regions 100a.

Detailed description of the dielectric structure layer is not repeated herein.

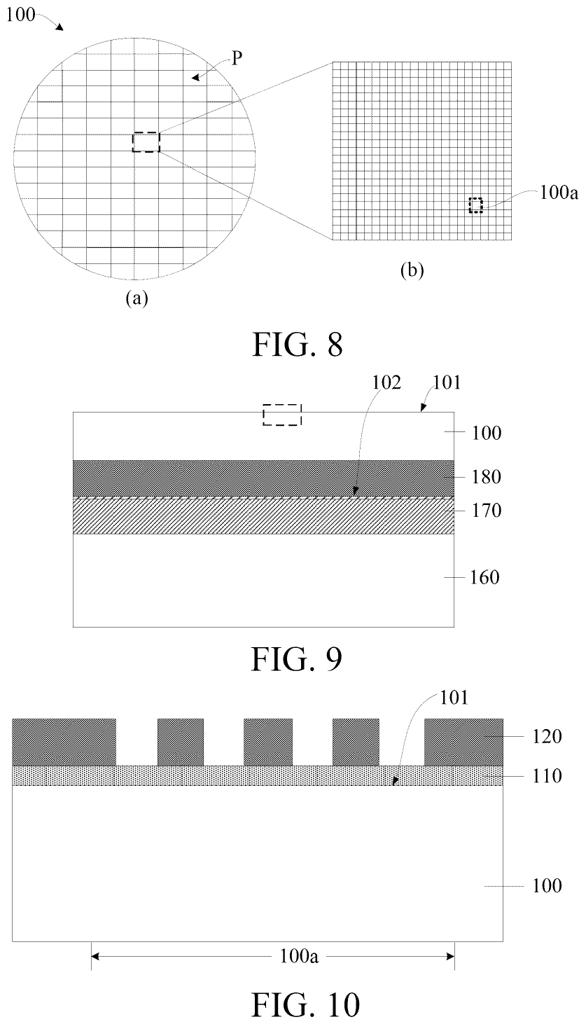

The present disclosure further provides a method for forming a photoelectric sensor. FIG. 8 to FIG. 13 are schematic structural diagrams corresponding to steps in one form of a method for forming a photoelectric sensor according to the present disclosure.

With reference to FIG. 8 to FIG. 10, FIG. 8(a) is a top view of the base, FIG. 8(b) is a partial enlarged view of any photosensitive pixel region in FIG. 8(a), FIG. 9 is a cross-sectional view corresponding to FIG. 8(a), and FIG. 10 is a partial enlarged view of a position shown by a dashed-line frame in FIG. 9. A base 100 is provided. The base 100 has a light receiving surface 101. The base 100 includes a pixel unit region 100a. A mask layer 110 covering the light receiving surface 101 is formed on the base 100.

In an example, the photoelectric sensor is a TOF sensor, for example. Specifically, the photoelectric sensor may be a DTOF sensor.

In other implementations, the photoelectric sensor may be a CCD image sensor, a CMOS image sensor, an iTOF sensor, or the like.

The base 100 is configured to provide a process platform for a subsequent manufacturing procedure of the process.

In some implementations, the base 100 is a silicon base. That is to say, a material of the base 100 is silicon.

In some implementations, the base 100 includes a photosensitive pixel region P, and the photosensitive pixel region P includes a plurality of pixel unit regions 100a distributed in a matrix.

The photosensitive pixel region P is used for receiving optical signals so as to convert the optical signals to electrical signals.

In the base 100, a plurality of photosensitive pixel regions P are arranged. The plurality of photosensitive pixel regions P are arranged in a matrix. The pixel unit region 100a is used for forming a single pixel.

In some implementations, the light receiving surface 101 is a surface for receiving light.

Specifically, the base 100 is a pixel wafer, and the light receiving surface 101 is a first surface. The base 100 further includes a second surface 102 opposite to the first surface.

In some implementations, the first silicon base 100 is a BSI pixel wafer.

Correspondingly, the light receiving surface 101 is a back side of the wafer, and the second surface 102 is a front side of the wafer.

In some implementations, only a part of the photosensitive pixel region P and the pixel unit region 100a is shown in the figure. The pixel unit region 100a may further include device structures such as a photoelectric element (for example, a photodiode). The photodiode may be a BSI single-photon avalanche diode (SPAD). For simplicity, detailed structures of the above components are not shown in this embodiment of the present disclosure.

In some implementations, the base 100 is defined as a first base 100. In this case, the method for forming a photoelectric sensor further includes: providing a second base 160 for use as a logic wafer; and bonding the second surface 102 of the first base 100 to the second base 160.

The second base 160 is used as a logic wafer configured to analyze and process electrical signals provided by the pixel wafer.

By arranging the photosensitive pixel region P and a logic region on the two wafers respectively and bonding the pixel wafer to the logic wafer, a larger pixel area can be obtained. In addition, a path through which light passes to reach the photoelectric element is shortened, and scattering of the light is reduced, so that the light is more focused, thereby improving a photosensitive capability of the photoelectric sensor in a weak light environment, and reducing system noise and crosstalk.

In some implementations, a logic transistor (not shown) is further formed in the second base 160. The logic transistor is configured to perform logic processing on the electrical signals provided by the pixel wafer. Specifically, the logic transistor may include a logic gate structure located on the second base 160 and a logic drain region and a logic source region respectively located in the second bases 160 on two sides of the logic gate structure.

In some implementations, the second surface 102 of the first base 100 is bonded to the second base 200 by hybrid bonding.

Specifically, in some implementations, a first interconnecting structure 180 is formed on the second surface 102 of the first base 100, and a second interconnecting structure 170 is formed on the second base 160. The pixel wafer may be bonded to the logic wafer by dielectric bonding and metal bonding between the first interconnecting structure 180 and the second interconnecting structure 170. For detailed description of the first interconnecting structure 180 and the second interconnecting structure 170, refer to the above embodiments.

It should be noted that, the above manner of bonding the first base 100 to the second base 160 is merely an example, and bonding between the first base 100 and the second base 160 is not limited thereto. For example, in other implementations, the first base may be directly bonded to the second base (for example, by fusion bonding and anodic bonding). Alternatively, the first base may be indirectly bonded to the second base (for example, by metal eutectic bonding, thermocompression bonding, and adhesive bonding).

In some implementations, the method for forming a photoelectric sensor further includes thinning the light receiving surface 101 of the first base 100 after bonding the second surface 102 of the first base 100 to the second base 160.

The light receiving surface 101 of the first base 100 is thinned to reduce a thickness of the first base 100 and correspondingly reduce an overall thickness of the photoelectric sensor.

In an example, a thinning process for the light receiving surface 101 of the first base 100 includes a chemical mechanical polishing (CMP) process. The CMP process is a global planarization process, which helps improve an overall flatness of a device plane and provide a flat and smooth surface for subsequent processes.

A manner of thinning the light receiving surface 101 of the first base 100 is not limited thereto. For example, In other implementations, the thinning process may be an etching process, a combination of an etching process and a CMP process, or the like.

The mask layer 110 is used as an etching mask for the patterned base 100 after being subsequently patterned.

In some implementations, a material of the mask layer 110 includes SiO₂. In other implementations, the material of the mask layer may be SiN. Alternatively, the mask layer may be formed by an in-situ steam generation (ISSG) process.

In some implementations, in the step of providing the base 100, a patterned photoresist 120 is further formed on the mask layer 110.

The patterned photoresist 120 is used as an etching mask for patterning the mask layer 110.

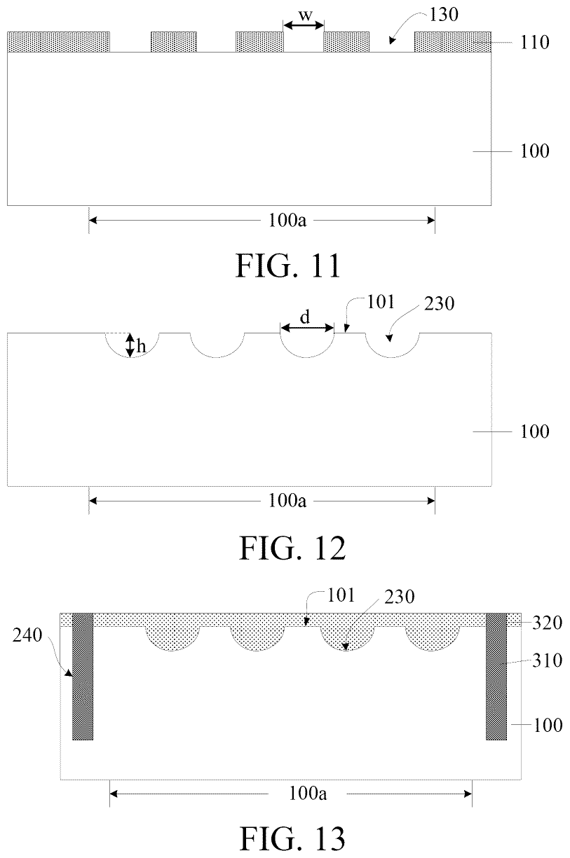

Referring to FIG. 11, the mask layer 110 is patterned, to form a plurality of mask openings 130 in the mask layer 110 in the pixel unit region 100a.

Specifically, the mask layer 110 is patterned using the patterned photoresist 120 as a mask to form the mask openings 130.

In some implementations, the mask layer 110 is patterned using a wet etching process.

The wet etching process has relatively low costs and simple operation steps, and can realize a relatively large etch selectivity, which helps reduce damage to the base 100 during the patterning of the mask layer 110.

In other implementations, the mask layer may be patterned using a dry etching process.

In some implementations, an etching solution of the wet etching process includes an HF solution, the material of the base 100 is Si, and the material of the mask layer 110 is SiO₂. The HF solution can have a relatively large etch selectivity to SiO₂ and Si. Therefore, damage to the base 100 can be reduced during the etching of the mask layer 110.

It should be noted that, in the step of patterning the mask layer 110, an opening size w of each of the mask openings 130 should be neither excessively large nor excessively small. Subsequently, the base 100 is etched by using an isotropic wet etching process to form a light trapping groove with an arcuate surface. The isotropic wet etching process has a same etching rate in all directions. Due to blocking by the mask layer 110, it is easier to etch the base 100 at a middle portion of the mask opening 130 than the bases 100 at both sides. Therefore, a depth by which the base 100 is etched decreases from the middle part of the mask opening 130 toward the two sides, thereby forming a light trapping groove with an arcuate surface. If the opening size w of the mask opening 130 is excessively large, an area of the middle part of the mask opening 130 is relatively large, and therefore the base 100 having a relatively large area located in the middle part of the mask opening 130 tends to be etched by a close depth in the subsequent step of etching the base 100, which tends to form a light trapping groove having a plane bottom. Therefore, it is difficult to form a light trapping groove with an arcuate shape, resulting in difficulty in increasing the photosensitive area of the photoelectric sensor and in improving the photosensitive performance of the photoelectric sensor. If the opening size w of the mask opening 130 is excessively small, an opening size of the subsequently formed light trapping groove tends to be excessively small. Therefore, it is difficult to obtain a relatively large photosensitive area, resulting in difficulty in improving the performance of the photoelectric sensor. Therefore, In some implementations, the opening size w of the mask opening 130 ranges from 100 nm to 300 nm.

In some implementations, after patterning the mask layer 110, the method further includes: removing the photoresist 120 to prepare for subsequent etching of the base 110 to form light trapping grooves.

Referring to FIG. 12, the base 100 is etched along the mask openings 130 using an isotropic wet etching process, to form

a plurality of light trapping grooves 230. A surface shape of each of the light trapping grooves 230 is arcuate.

The light trapping groove 230 helps improve an optical transmittance of the photosensitive pixel region P and increase photoelectric conversion efficiency, thereby improving optical sensitivity of the photoelectric sensor.

Specifically, the light trapping groove 230 is arranged above the photoelectric element, which can slow down a change of a refractive index between the air and the first surface 101, and reduce a high reflectivity at an interface caused by a sudden change of the refractive index, so that more light can enter the photoelectric element, and a transmittance of the incident light can be improved. In addition, arranging the light trapping groove 230 in the pixel unit region 100a of the first surface 101 can help disperse the incident light to a plurality of angles, and increase an effective path of the light, thereby realizing trapping of the light.

In some implementations, the base 100 is etched along the mask openings 130 using the isotropic wet etching process to form a plurality of light trapping grooves 230, and the surface shape of each of the light trapping grooves 230 is arcuate, which helps increase a photosensitive area of the photoelectric sensor in the pixel unit region 100a. Therefore, an optical path difference of incident light increases, which helps improve an optical localization capability of the photoelectric sensor. Moreover, the etching using the isotropic wet etching process is less restricted by a lattice of a material of the base 100, parameters of the process are highly controllable, and sizes of and a spacing between the formed light trapping grooves 230 can be controlled through the mask openings 130 and the etching process, which improves process flexibility of forming the light trapping grooves 230, and therefore help form light trapping grooves with relatively high morphological quality, thereby improving the photosensitive performance of the photoelectric sensor.

Specifically, the base 100 is etched using an isotropic wet etching process. The isotropic wet etching process has a same etching rate of all directions. Due to blocking by the mask layer 110, it is easier to etch the base at the middle portion of the mask opening 130 than the base at the two sides. Therefore, the depth by which the base 100 is etched decreases from the middle part of the mask opening 130 toward the two sides, thereby forming a light trapping groove 230 with an arcuate surface.

A plurality of light trapping grooves 230 are arranged. The plurality of light trapping grooves 230 are distributed in a matrix, so as to improve a density of light trapping grooves 230 in each pixel unit region 100a, thereby helping further increase the optical transmittance.

The density of the light trapping grooves 230 is a ratio of an area of openings of all light trapping grooves 230 in the photosensitive pixel region P to an area of the photosensitive surface 101 of the photosensitive pixel region P.

In some implementations, the surface shape of the light trapping groove 230 is hemispherical, so that the morphological quality of the light trapping groove 230 is relatively high, which helps further increase the photosensitive area of the photoelectric sensor and improve the optical localization capability of the photoelectric sensor, thereby further improving the photosensitive performance of the photoelectric sensor.

It should be noted that a maximum depth h of the light trapping groove 230 should be neither excessively large nor excessively small. If the maximum depth h of the light trapping groove 230 is excessively large, a thickness of the remaining base 100 at a bottom of the light trapping groove 230 is excessively small. That is to say, for light incident on the bottom of the light trapping groove 230, photons cannot be absorbed effectively. In particular, for incident light with a relatively longer wavelength such as a near-infrared ray, the base 100 at the bottom of the light trapping groove 230 absorbs the light much less effectively, affecting the absorption of the light by the photoelectric sensor. If the maximum depth h of the light trapping groove 230 is excessively small, it is difficult to form a relatively desirable arcuate surface shape for the light trapping groove 230, or even the surface shape approximates a flat surface shape, resulting in excessively few reflections of the incident light and difficulty in increasing the optical path difference. As a result, it is difficult to improve the photosensitive performance of the photoelectric sensor. Therefore, in some implementations, the maximum depth h of the light trapping groove 230 ranges from 150 nm to 600 nm.

The maximum depth h of the light trapping groove 230 is a depth at the lowest point of the light trapping groove 230 with the arcuate surface.

It should be further noted that a transverse opening size d of the light trapping groove 230 should be neither excessively large nor excessively small. If the transverse opening size d of the light trapping groove 230 is excessively large, a spacing between adjacent light trapping grooves 230 is excessively small, that is, an area of a platform of the light receiving surface 101 between adjacent light trapping grooves 230 is excessively small. During the etching process for forming the light trapping groove 230, a mask layer 110 is further formed on the platform of the light receiving surface 101 between adjacent light trapping grooves 230. Therefore, the area of the platform of the light receiving surface 101 between adjacent light trapping grooves 230 is excessively small, which tends to cause the mask layer 110 on the platform of the light receiving surface 101 between adjacent light trapping grooves 230 to fall into a pickling tank during the etching process for forming the light trapping groove 230. As a result, the pickling tank is polluted, affecting other subsequent manufacture procedures using the pickling tank. If the transverse opening size d of the light trapping groove 230 is excessively small, the spacing between adjacent light trapping grooves 230 is excessively large. That is to say, if the area of the platform of the light receiving surface 101 between adjacent light trapping grooves 230 is excessively large, an area percentage of the area of the platform of the light receiving surface 101 between adjacent light trapping grooves 230 in the pixel unit region 100a is excessively large. Correspondingly, if the density of light trapping grooves 230 is excessively small, it is difficult to obtain a relatively large photosensitive area, resulting in difficulty in improving the performance of the photoelectric sensor. Therefore, in some implementations, the transverse opening size d of the light trapping groove 230 ranges from 150 nm to 600 nm.

In some implementations, in the step of etching the base 100 by using the isotropic wet etching process, an etching solution of the wet etching process includes an HNA solution.

The HNA solution is a mixed solution of HF, HNO₃, and CH₃COOH, which has an isotropic etching property for Si, and the material of the base 100 is Si. Therefore, etching the base 100 by using the HNA solution can form a light trapping groove 230 with an arcuate surface.

It should be noted that an etching time of the wet etching process should be neither excessively long nor excessively short. If the etching time of the wet etching process is excessively long, the base 100 located in the middle part of the mask opening 130 tends to be etched by an increasingly close depth, which tends to form a light trapping groove 230 with a plane bottom. Therefore, it is difficult to form a light trapping groove 230 with an arcuate shape, resulting in difficulty in increasing the photosensitive area of the photoelectric sensor and in improving the photosensitive performance of the photoelectric sensor. If the etching time of the wet etching process is excessively short, a depth of the formed light trapping groove 230 tends to be excessively small, and it is difficult to form a relatively desirable arcuate surface shape for the light trapping groove 230, or even the surface shape approximates a flat surface shape, resulting in excessively few reflections of the incident light and difficulty in increasing the optical path difference. As a result, it is difficult to improve the photosensitive performance of the photoelectric sensor. Therefore, in some implementations, the etching time of the wet etching process ranges from 20 s to 45 s.

In some implementations, after forming the light trapping groove 230, the method further includes: removing the mask layer 110 to prepare for subsequent formation of the light-transmissive layer and the light isolation structure.

In some implementations, the mask layer 110 is removed by using a wet etching process.

The wet etching process has relatively low costs and simple operation steps, and can realize a relatively large etch selectivity, which helps reduce damage to the base 100 during the removal of the mask layer 110.

In some implementations, an etching solution of the wet etching process includes an HF solution, the material of the base 100 is Si, and the material of the mask layer 110 is SiO₂. The HF solution can have a relatively large etch selectivity to SiO₂ and Si. Therefore, damage to the base 100 can be reduced during the removal of the mask layer 110.

Referring to FIG. 13, after removing the mask layer 110, the method further includes: patterning the base 100 to form a trench 240 in the base 100 between adjacent pixel unit regions 100a; forming a light isolation structure 310 in the trench 240; and forming a light-transmissive layer 320 filling the light trapping groove 230 and covering the light receiving surface 101 in the pixel unit region 100a.

Filling the light trapping groove 230 with the light-transmissive layer 320 helps ensure an effect of the light trapping groove 230 for improving the optical transmittance of the photosensitive pixel region P, thereby improving process integration and process compatibility. In addition, the light-transmissive layer 320 is further configured to planarize each film layer on the light receiving surface 101.

In some implementations, a material of the light-transmissive layer 320 includes silicon oxide, silicon nitride, silicon oxynitride, or silicon carbide.

The trench 240 provides a space for the subsequent formation of the light isolation structure 310. The light isolation structure 310 is configured to reduce optical crosstalk between adjacent pixel unit regions 100a.

In some implementations, a material of the light isolation structure 310 includes one or more of tungsten, aluminum, copper, titanium, titanium nitride, tantalum, tantalum nitride, silicon oxide, aluminum oxide, or polysilicon.

Specifically, in some implementations, before forming the light isolation structure 310 and the light-transmissive layer 320, the method further includes: forming a conformal dielectric layer (not shown) covering an inner surface of the light trapping groove 230, the light receiving surface 101, and a sidewall and a bottom of the trench 240.

The conformal dielectric layer can electrically isolate adjacent pixel unit regions 100a, which helps prevent electrical crosstalk between the adjacent pixel unit regions 100a. A conformal dielectric layer 140 located on a surface between the light isolation structure 310 and the base 100 can electrically isolate the adjacent pixel unit regions 100a, which correspondingly helps prevent electrical crosstalk between the adjacent pixel unit regions 100a.

Detailed description of the dielectric structure layer is not repeated herein.

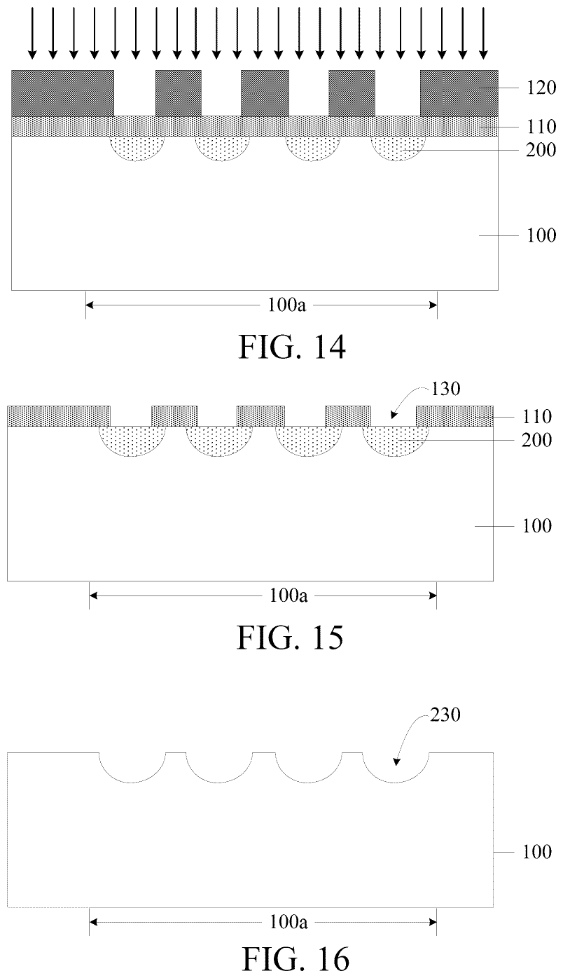

FIG. 14 to FIG. 16 are schematic structural diagrams corresponding to steps in another form of a method for forming a semiconductor structure according to the present disclosure.

Similarities between this form and the foregoing form are not described herein again. A difference between this form and the above form lies in that ion implantation is further performed on the base before the mask layer is patterned, to form a doped layer.

Referring to FIG. 14, before patterning the mask layer 110, the method further includes: performing ion implantation on the base 100 using the patterned photoresist 120 as a mask, to form a doped layer 200 with an arcuate contour boundary, where the doped layer 200 has an etch selectivity to the base 100.

Ion implantation is performed on the base 100, and the base 100 doped with ions is used as the doped layer 200.

It should be noted that, during the ion implantation on the base 100, due to blocking by the photoresists 120, ion implantation is easier to perform for the base 100 at a middle portion of an opening between two adjacent photoresists 120 than for the base 100 at both sides of the opening. Therefore, an ion implantation depth of the base 100 decreases from the middle part of the mask opening 130 toward the two sides, thereby forming a doped layer 200 with an arcuate surface. In this way, after the doped layer 200 is subsequently removed, a light trapping groove with an arcuate surface can be formed.

In some implementations, the doped layer 200 is used as a sacrificial layer for the subsequent etching of the base 100 to form light trapping grooves, which holds a space for the subsequent formation of the light trapping grooves. By performing the ion implantation on the base 100, the doped layer 200 having an etch selectivity to the base 100 can be formed, so that damage to the base 100 is reduced in the subsequent step of removing the doped layer 200.

In some implementations, ions during the ion implantation include B, P, C, or Ge.

In some implementations, the material of the base 100 is Si. Implanting the ions B, P, C, or Ge into Si can change a resistivity of Si, thereby forming the doped layer 200 with a resistivity different from that of the base 100. In this way, the doped layer 200 has an etch selectivity to the base 100.

It should be noted that, parameters during the ion implantation, such as an implantation dose should be neither excessively large nor excessively small. If the implantation dose is excessively large, an ion implantation range tends to be excessively large, resulting in difficulty in controlling the manufacture procedure. If the implantation dose is excessively small, a reaction time during the ion implantation is excessively long, efficiency of the manufacture process decreases, a shape of the doped layer 200 is affected, and a process effect cannot be achieved. In addition, etching rates of the doped layer 200 and the base 100 tend to be similar, increasing a probability of damage to the base 100 in the subsequent process of removing the doped layer 200. Therefore, In some implementations, the implantation dose ranges from 1E15 atoms/cm² to 1E17 atoms/cm².

It should be further noted that, parameters during the ion implantation, such as an implantation energy should be neither excessively large nor excessively small. If the implantation energy is excessively large, an ion implantation range tends to be excessively large, resulting in difficulty in controlling the manufacture procedure. If the implantation energy is excessively small, a reaction time during the ion implantation is excessively long, efficiency of the manufacture process decreases, a shape of the doped layer 200 is affected, and a process effect cannot be achieved. Therefore, in some implementations, the implantation energy ranges from 20 keV to 100 keV.

It should be noted that the etch selectivity between the doped layer 200 and the base 100 should not be excessively small. If the etch selectivity between the doped layer 200 and the base 100 is excessively small, in the subsequent step of removing the doped layer 200, the base 100 is easily damaged, which affects the shape of the formed light trapping groove, thus affecting the photosensitive performance of the photoelectric sensor. Therefore, in some implementations, parameters during the ion implantation satisfy: an etch selectivity of the doped layer 200 to the base 100 is greater than or equal to 50:1.

Referring to FIG. 15, after removing the photoresist 120 and before removing the doped layer 200 by using the isotropic wet etching process, the method further includes: performing thermal treatment on the doped layer 200.

Thermal treatment is performed on the doped layer 200, so that ions are diffused through the thermal treatment, which helps expand a volume occupied by the doped layer 200, thereby increasing a surface area of a light trapping groove formed subsequently, and further helps obtain a relatively regular arcuate surface through ion diffusion, thereby subsequently obtaining a light trapping groove having a surface with relatively high morphological quality.

Specifically, in some implementations, the thermal treatment includes a rapid thermal annealing process.

The rapid thermal annealing process is easy to operate, and process parameters thereof are easy to control, so that the volume occupied by the doped layer 200 can be effectively expanded, and the shape of the doped layer 200 can be effectively regulated.

Referring to FIG. 16, the step of etching the base 100 using the isotropic wet etching process includes: removing the doped layer 200 by using the isotropic wet etching process and by using an interface between the doped layer 200 and the base 100 as an etching stop position.

Since the doped layer 200 has the etch selectivity to the base 100, during the removal of the doped layer 200 using the interface between the doped layer 200 and the base 100 as an etching stop position, an etching amount can be effectively controlled, which helps form the light trapping groove 230 having an arcuate surface with high shape quality, and damage to the base 100 can be reduced.

Specifically, during the etching, the etch selectivity is realized by controlling a resistivity of a material in contact with an etching solution. The resistivity of the doped layer 200 is different from that of the base 100. The etching solution is controlled to perform etching when the etching solution contacts the doped layer 200 and to stop etching when the etching solution contacts the base 100 with a different resistivity, so that the light trapping groove 230 can be formed by using the interface between the doped layer 200 and the base 100 as the etching stop position.

In some implementations, in the step of etching the base 100 using the isotropic wet etching process, an etching solution of the wet etching process includes an HNA solution.

The HNA solution is a mixed solution of HF, HNO₃, and CH₃COOH, which has an etch selectivity to Si and Si with doped ions. The material of the base 100 is Si, and the doped layer 200 is Si doped with ions. Therefore, etching the base 100 by using the HNA solution can realize the etch selectivity of the doped layer 200 to the base 100, and a light trapping groove 230 with an arcuate surface can be formed by using the interface between the doped layer 200 and the base 100 as an etching stop position.

Yet another form of the present disclosure provides an electronic device, including the photoelectric sensor provided in the forms of the present disclosure.

The electronic device in this form may be any electronic product or device with a photoelectric sensing function, such as a mobile phone, a tablet computer, a notebook computer, a navigator, a camera, a video camera, a sweeping robot, a virtual reality (VR) device, or an augmented reality (AR) device, or may be any intermediate product that includes the above photoelectric sensor.

It will be appreciated from the above description that, embodiments and implementations of the present disclosure significantly increase the photosensitive area of the photoelectric sensor, and increases reflections of the incident light between photosensitive surfaces. Therefore, the optical path difference of the incident light increases, which helps improve the optical localization capability of the photoelectric sensor, thereby improving the photosensitive performance of the photoelectric sensor. The photoelectric sensor provided in the embodiments of the present disclosure correspondingly helps improve performance of the electronic device, thereby improving user experience.

Although the present disclosure is described above, the present disclosure is not limited thereto. Any person skilled in the art may make various changes and modifications without departing from the spirit and the scope of the present disclosure. Therefore, the protection scope of the present disclosure should be subject to the scope defined by the claims.

What is claimed is:

1. A photoelectric sensor, comprising:
a base, having a light receiving surface and comprising a pixel unit region; and
a plurality of light trapping grooves, the light trapping grooves arranged in a part of the base in a thickness direction in the pixel unit region and arranged on a side of the light receiving surface of the base, wherein a surface shape of each of the light trapping grooves is arcuate.

2. The photoelectric sensor according to claim 1, wherein the surface shape of the light trapping groove is hemispherical.

3. The photoelectric sensor according to claim 1, further comprising a light-transmissive layer filling the light trapping groove and covering the light receiving surface in the pixel unit region.

4. The photoelectric sensor according to claim 1, wherein:
the base comprises a photosensitive pixel region, and the photosensitive pixel region comprises a plurality of pixel unit regions distributed in a matrix; and
the photoelectric sensor further comprises a light isolation structure arranged in the base between adjacent pixel unit regions.

5. The photoelectric sensor according to claim 1, wherein a maximum depth of the light trapping groove ranges from 150 nm to 600 nm.

6. The photoelectric sensor according to claim 1, wherein in a direction parallel to a surface of the base, a transverse opening size of the light trapping groove ranges from 150 nm to 600 nm.

7. The photoelectric sensor according to claim 1, wherein a material of the base comprises silicon.

8. A method for forming a photoelectric sensor, comprising:
providing a base, wherein the base has a light receiving surface, the base comprising a pixel unit region, and a mask layer covering the light receiving surface is formed on the base;
patterning the mask layer to form a plurality of mask openings in the mask layer in the pixel unit region; and
etching the base along the mask openings using an isotropic wet etching process to form a plurality of light trapping grooves, wherein a surface shape of each of the light trapping grooves is arcuate.

9. The method for forming a photoelectric sensor according to claim 8, wherein the surface shape of the light trapping groove is hemispherical.

10. The method for forming a photoelectric sensor according to claim 8, wherein in the step of patterning the mask layer, an opening size of each of the mask opening ranges from 100 nm to 300 nm.

11. The method for forming a photoelectric sensor according to claim 8, wherein in the step of etching the base using the isotropic wet etching process, an etching time of the wet etching process ranges from 20 s to 45 s.

12. The method for forming a photoelectric sensor according to claim 8, wherein the mask layer is patterned using a wet etching process.

13. The method for forming a photoelectric sensor according to claim 8, wherein:
in the step of providing the base, a patterned photoresist is further formed on the mask layer;
before patterning the mask layer, the method further comprises: performing ion implantation on the base by using the patterned photoresist as a mask, to form a doped layer with an arcuate contour boundary, wherein the doped layer has an etch selectivity to the base;
in the step of patterning the mask layer, the mask layer is patterned using the patterned photoresist as a mask;
after patterning the mask layer, the method further comprises: removing the photoresist; and
the step of etching the base by using the isotropic wet etching process comprises: removing the doped layer using the isotropic wet etching process and using an interface between the doped layer and the base as an etching stop position.

14. The method for forming a photoelectric sensor according to claim 13, wherein in the step of performing the ion implantation on the base, ions during the ion implantation comprise at least one of B, P, C, or Ge, and parameters during the ion implantation comprise an implantation dose ranging from 1E15 atoms/cm² to 1E17 atoms/cm² and an implantation energy ranging from 20 keV to 100 keV.

15. The method for forming a photoelectric sensor according to claim 13, wherein in the step of performing the ion implantation on the base, parameters during the ion implantation satisfy: an etch selectivity of the doped layer to the base is greater than or equal to 50:1.

16. The method for forming a photoelectric sensor according to claim 13, wherein after removing the photoresist and before removing the doped layer using the isotropic wet etching process, the method further comprises: performing thermal treatment on the doped layer.

17. The method for forming a photoelectric sensor according to claim 16, wherein the thermal treatment comprises a rapid thermal annealing process.

18. The method for forming a photoelectric sensor according to claim 8, wherein in the step of etching the base by using the isotropic wet etching process, an etching solution of the wet etching process comprises an HNA solution.

19. The method for forming a photoelectric sensor according to claim 8, wherein:
in the step of providing the base, the base comprises a photosensitive pixel region, and the photosensitive pixel region comprises a plurality of pixel unit regions distributed in a matrix;
after forming the light trapping groove, the method further comprises: removing the mask layer; and
after removing the mask layer, the method further comprises:
patterning the base to form a trench in the base between adjacent pixel unit regions;
forming a light isolation structure in the trench; and
forming a light-transmissive layer filling the light trapping groove and covering the light receiving surface in the pixel unit region.

20. An electronic device, comprising: the photoelectric sensor according to claim 1.
